(19) United States
(12) Patent Application Publication
(10) Pub. No.: US 2025/0356940 A1
(43) Pub. Date: Nov. 20, 2025

(54) MEMORY SYSTEM, ELECTRONIC PRODUCT AND OPERATING METHOD OF MEMORY SYSTEM

(71) Applicant: YANGTZE MEMORY TECHNOLOGIES CO., LTD., Wuhan (CN)

(72) Inventors: YuHeng LIU, Wuhan (CN); Rongrong WU, Wuhan (CN)

(21) Appl. No.: 18/886,660

(22) Filed: Sep. 16, 2024

(30) Foreign Application Priority Data
May 17, 2024 (CN) 2024106221232

(51) Int. Cl. G11C 29/50

(52) U.S. Cl. CPC G11C 29/50004; G11C 2029/5006

(57) ABSTRACT

The present disclosure includes a memory system, an electronic product and an operating method of the memory system. In an example of the present disclosure, a current test circuit is packaged inside the memory system including memory, which allows directly testing current on memory pins by the current test circuit. As such, on one hand, it is possible to test current of the memory without establishing any test table, and the test process is not environment-limited. On the other hand, because the current test circuit can test current on memory pins at any time, it is possible to monitor the current data of the memory in real time in the operation of memory, thereby improving accuracy of the power consumption evaluation.

### CROSS-REFERENCE TO RELATED APPLICATIONS

The present application claims priority to Chinese Patent Application No. 2024106221232, which was filed May 17, 2024, is titled “STORAGE SYSTEM, ELECTRONIC PRODUCT AND OPERATING METHOD OF STORAGE SYSTEM,” and is hereby incorporated herein by reference in its entirety.

### TECHNICAL FIELD

Examples of the present disclosure relate to memory technology field, particularly to a memory system, an electronic product and an operating method of the memory system.

### BACKGROUND

At present, in order to evaluate power consumption of a memory, it is possible to test the current of the memory and in turn evaluate the power consumption of the memory according to the tested current and the rated operating voltage. In prior art, a test table may be established which includes an oscilloscope by which the current of a memory is tested. For this test approach, on the one hand, the test process is complicated since a test table needs to be established; and on the other hand, the oscilloscope can only test current of the memory in several discontinuous specific periods, which will influence the accuracy of the power consumption evaluation.

### SUMMARY

Examples of the present disclosure provide a memory system, an electronic product and an operating method of the memory system. The technical solution is as follows.

In one aspect, there is provided a memory system comprising a first memory and a current test circuit, the first memory has a first pin, the current test circuit has a first test terminal connected with the first pin and a data output terminal; the first pin is configured to power the first memory through a first power supply circuit; the current test circuit is configured to acquire a current on the first pin during the operation of the first memory and output the current on the first pin via the data output terminal.

In some examples, the first pin comprises a plurality of first sub-pins, the first test terminal comprises a plurality of first sub-test-terminals, each first sub-test-terminal is connected with one first sub-pin, and the current test circuit further has a control terminal; the current test circuit is further configured to receive a control instruction via the control terminal, the control instruction indicating that current on a target first sub-pin in the plurality of first sub-pins needs to be acquired; the current test circuit is further configured to acquire the current on the target first sub-pin in response to the control instruction.

In some examples, the control instruction carries a bit sequence comprising a plurality of bits in one-to-one correspondence with the plurality of first sub-pins; a value of a target bit in the bit sequence is a first bit value, and a value of other bits than the target bit in the bit sequence is a second bit value, the target bit is the bit corresponding to the target first sub-pin.

In some examples, the current test circuit comprises an analog signal acquisition circuit and an analog-to-digital conversion circuit, an input terminal of the analog signal acquisition circuit is connected with the first test terminal and an output terminal of the analog signal acquisition circuit is connected with the input terminal of the analog-to-digital conversion circuit, and an output terminal of the analog-to-digital conversion circuit is connected with the data output terminal; the analog signal acquisition circuit is configured to acquire current on the first pin to obtain a current analog signal; and the analog-to-digital conversion circuit is configured to convert the current analog signal into a current digital signal.

In some examples, the current test circuit further comprises a buffer, the output terminal of the analog-to-digital conversion circuit is connected with an input terminal of the buffer and an output terminal of the buffer is connected with the data output terminal; the buffer is configured to buffer the current digital signal; and the buffer is further configured to output the current digital signal to the data output terminal in response to a data reading instruction received at the output terminal of the buffer.

In some examples, the output terminal of the buffer is in communication with the data output terminal via a serial communication bus I2C.

In some examples, the first pin comprises a plurality of first sub-pins, the first test terminal comprises a plurality of first sub-test-terminals, and the plurality of first sub-test-terminals are connected with the plurality of first sub-pins in one-to-one correspondence, the analog signal acquisition circuit comprises a plurality of current sensors in one-to-one correspondence with the plurality of first sub-pins, an input terminal of each current sensor in the plurality of current sensors is connected with the corresponding first sub-pin via one first sub-test-terminal and an output terminal of each current sensor is connected with the input terminal of the analog-to-digital conversion circuit; and each current sensor is configured to acquire current on the corresponding first sub-pin.

In some examples, the current test circuit further has a control terminal, the analog signal acquisition circuit further comprises a sensing control circuit having a plurality of control terminals connected with the control terminals of the plurality of current sensors respectively and an input terminal connected with the control terminal of the current test circuit; the sensing control circuit is configured to control on or off of each current sensor in the plurality of current sensors in response to the control instruction received at the input terminal of the sensing control circuit.

In some examples, the memory system further comprises a second memory having a second pin, and the current test circuit further has a second test terminal connected with the second pin; the second pin is configured to power the second memory through a second power supply circuit; and the current test circuit is further configured to acquire a current on the second pin during the operation of the second memory and output the current on the second pin via the data output terminal.

In some examples, the first memory comprises a nonvolatile memory and the second memory comprises a volatile memory.

In another aspect, there is provided an electronic product comprising: the memory system of any one of the above-described aspects; and a host coupled to the memory system and configured to control the memory system.

In another aspect, there is provided an operating method of a memory system comprising a first memory having a first pin, and a current test circuit; the method comprises: receiving, by the current test circuit, a current signal indicating a current on the first pin; sending, by the current test circuit, a test data based on the current signal, the test data comprising a current data indicating the current on the first pin.

In some examples, the first pin comprises a plurality of first sub-pins; before receiving, by the current test circuit, the current signal, the method further comprises: receiving, by the current test circuit, a control instruction indicating that a current on a target first sub-pin in the plurality of first sub-pins needs to be acquired; said receiving, by the current test circuit, the current signal comprises: receiving, by the current test circuit, a target current signal indicating a current on the target first sub-pin; wherein the test data comprises the target current data indicating the current on the target first sub-pin.

In some examples, the control instruction carries a bit sequence comprising a plurality of bits in one-to-one correspondence with the plurality of first sub-pins; a value of a target bit in the bit sequence is a first bit value, and a value of other bits than the target bit in the bit sequence is a second bit value, and the target bit is the bit corresponding to the target first sub-pin.

In some examples, the current test circuit comprises a buffer for storing the test data; said sending, by the current test circuit, the test data based on the current signal comprises: receiving, by the buffer, a data reading instruction; and sending, by the buffer, the test data in response to the data reading instruction.

In another aspect, there is provided an operating method of a memory system comprising a first memory having a first pin, and a current test circuit; the method comprises: receiving, by a host, the test data from the current test circuit, the test data comprising a current data indicating the current on the first pin.

In some examples, the first pin comprises a plurality of first sub-pins; before receiving, by the host, the test data from the current test circuit, the method further comprises: sending, by the host, a control instruction to the current test circuit, the control instruction indicating that a current on a target first sub-pin in the plurality of first sub-pins needs to be acquired; wherein the test data comprises the current data indicating the current on the target first sub-pin.

In some examples, the control instruction carries a bit sequence comprising a plurality of bits in one-to-one correspondence with the plurality of first sub-pins; a value of a target bit in the bit sequence is a first bit value, and a value of other bits than the target bit in the bit sequence is a second bit value, the target bit is the bit corresponding to the target first sub-pin.

In some examples, before receiving, by the host, the test data from the current test circuit, the method further comprises: sending, by the host, a data reading instruction to a buffer in the current test circuit, wherein the buffer stores the test data.

In the examples of the present disclosure, a current test circuit is packaged inside the memory system including a memory, which allows directly testing the current on the pin of the memory by the current test circuit. So, on the one hand, it is possible to test the current of the memory at any time and at any place without establishing any test table, and the test process is simple and not environment-limited. On the other hand, since the current test circuit can test the current on the pin of the memory at any time and at any place, it is possible to monitor the current data of the memory in real time in the operation of memory, thereby improving accuracy of the power consumption evaluation.

### BRIEF DESCRIPTION OF THE DRAWINGS

In order to explain the technical solutions in examples of the present disclosure more clearly, accompanying drawings required for describing examples will be described in brief below. It is obvious that the below described drawings are only some examples of the present disclosure and other drawings may be obtained according to these drawings without any creative work for those skilled in the art.

FIG. 1 is a diagram of a memory system provided in an example of the present disclosure;

FIG. 2 is a diagram of a memory card provided in an example of the present disclosure;

FIG. 3 is a diagram of another memory card provided in an example of the present disclosure;

FIG. 4 is a diagram of another memory card provided in an example of the present disclosure;

FIG. 5 is a diagram of a peripheral circuit provided in an example of the present disclosure;

FIG. 6 is an architecture diagram of a memory system including a current test circuit as provided in an example of the present disclosure;

FIG. 7 is an architecture diagram of another memory system including a current test circuit as provided in an example of the present disclosure;

FIG. 8 is an architecture diagram of another memory system including a current test circuit as provided in an example of the present disclosure;

FIG. 9 is an architecture diagram of another memory system including a current test circuit as provided in an example of the present disclosure;

FIG. 10 is an architecture diagram of another memory system including a current test circuit as provided in an example of the present disclosure;

FIG. 11 is an architecture diagram of another memory system including a current test circuit as provided in an example of the present disclosure;

FIG. 12 is a diagram of a SRAM storing current data in scrolling manner as provided in an example of the present disclosure;

FIG. 13 is an architecture diagram of another memory system including a current test circuit as provided in an example of the present disclosure;

FIG. 14 is an architecture diagram of another memory system including a current test circuit as provided in an example of the present disclosure;

FIG. 15 is an architecture diagram of another memory system including a current test circuit as provided in an example of the present disclosure;

FIG. 16 is an architecture diagram of another memory system including a current test circuit as provided in an example of the present disclosure;

FIG. 17 is a structure diagram of an electronic product provided in an example of the present disclosure;

FIG. 18 is a flow chart of an operating method of a memory system as provided in an example of the present disclosure; and

FIG. 19 is a flow chart of another operating method of a memory system as provided in an example of the present disclosure.

### DETAILED DESCRIPTION

In order to make the objects, technical solutions and advantages of examples of the present disclosure clearer, implementations of the present disclosure will be described in further detail below in connection with the accompanying drawings.

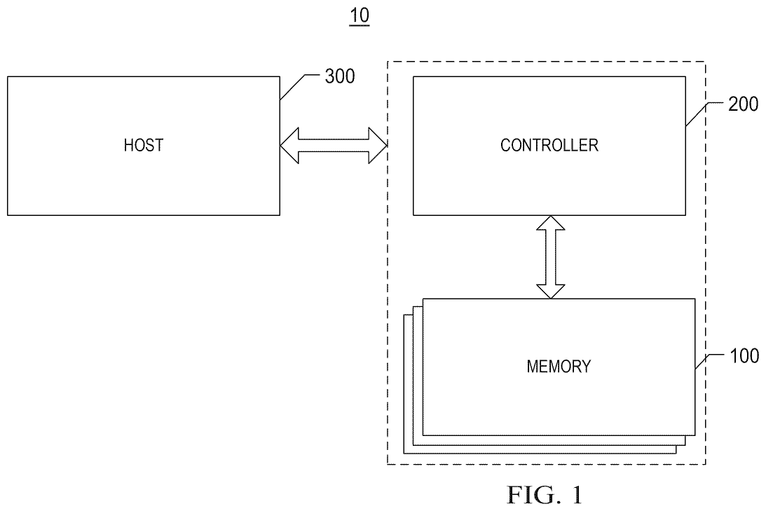

FIG. 1 is a diagram of a memory system 10 provided in an example of the present disclosure. As shown in FIG. 1, the memory system 10 includes: one or more memories 100 and a controller 200 coupled to the memories 100 and configured to control the memories 100.

The controller 200 can be configured to control operation of the memory 100, such as read, erase, and program operations. The controller 200 can also be configured to manage various functions with respect to the data stored or to be stored in the memory 100 including, but not limited to bad-block management, garbage collection, logical address to physical address conversion, wear leveling, etc. In some examples, the controller 200 may be further configured to process error correcting codes (ECCs) with respect to the data read from or written to the memory 100. Any other suitable functions may be performed by the controller 200 as well, for example, formatting the memory 100.

The controller 200 can also communicate with an external device according to a particular communication protocol. Illustratively, the controller 200 may communicate with the external device via at least one of various interface protocols. The interface protocols may be a universal serial bus (USB) protocol, a multi-media card (MMC) protocol, a peripheral component interconnect (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small drive interface (ESDI) protocol, an integrated drive electronics (IDE) protocol or a fire wire protocol etc.

In some examples, the controller 200 and the one or more memory 100 may be integrated into various types of electronic device. The electronic device can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory therein. In such a scenario, as shown in FIG. 1, the memory system 10 further includes a host 300. The controller 200 is coupled to the host 300. The controller 200 can manage the data stored in the memory 100 and communicate with the host 300 to implement functions of the above-described electronic device.

In some other examples, the controller 200 and the one or more memory 100 may be integrated into various types of memory devices.

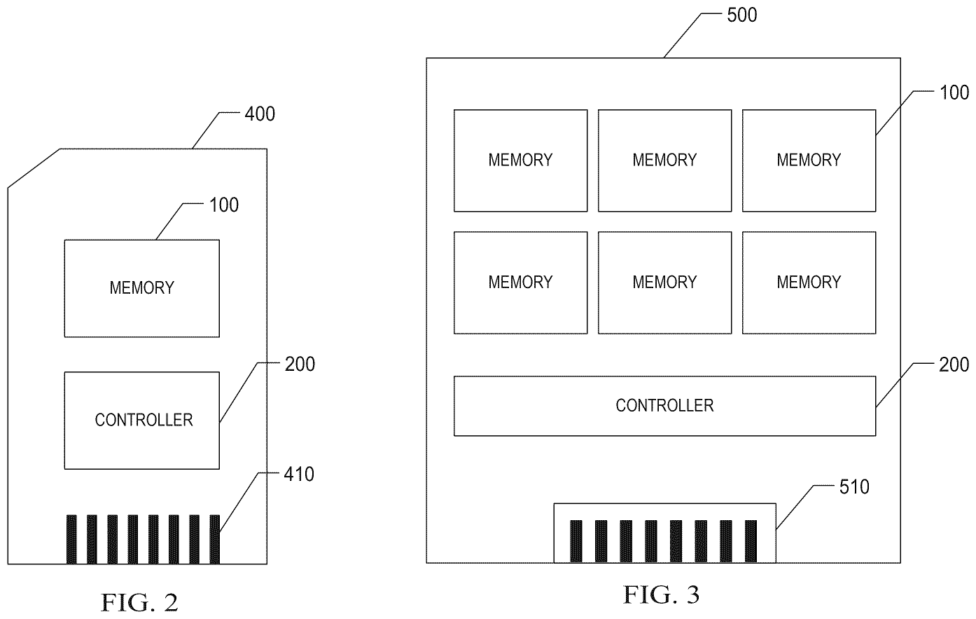

As an example, as shown in FIG. 2, the controller 200 and a single memory 100 can be integrated into a memory card 400. The memory card 400 may include a personal computer memory card international association (PCMCIA, PC) card, a Compact Flash (CF) card, a smart media (SM) card, a memory stick, a multi-media card (MMC), a reduced-size MMC (RS-MMC), a micro-MMC, a SD (Secure Digital) card, a universal flash storage (UFS) etc. As shown in FIG. 2, the memory card 400 may further include a connector 410 that couples the memory card 400 and the host.

As another example, as shown in FIG. 3, the controller 200 and multiple memory 100 can be integrated into a solid-state drive (SSD) 500. The SSD 500 can further include a connector 510 coupling the SSD 500 with a host. The memory capacity and/or operating speed of the SSD 500 are greater than the memory capacity and/or operating speed of the memory card 400.

Furthermore, the memory 100 in FIGS. 1 to 3 may be any memory involved in examples of the present disclosure, such as 3D NAND (Not And gate) memory. The structure of the memory 100 will be explained below.

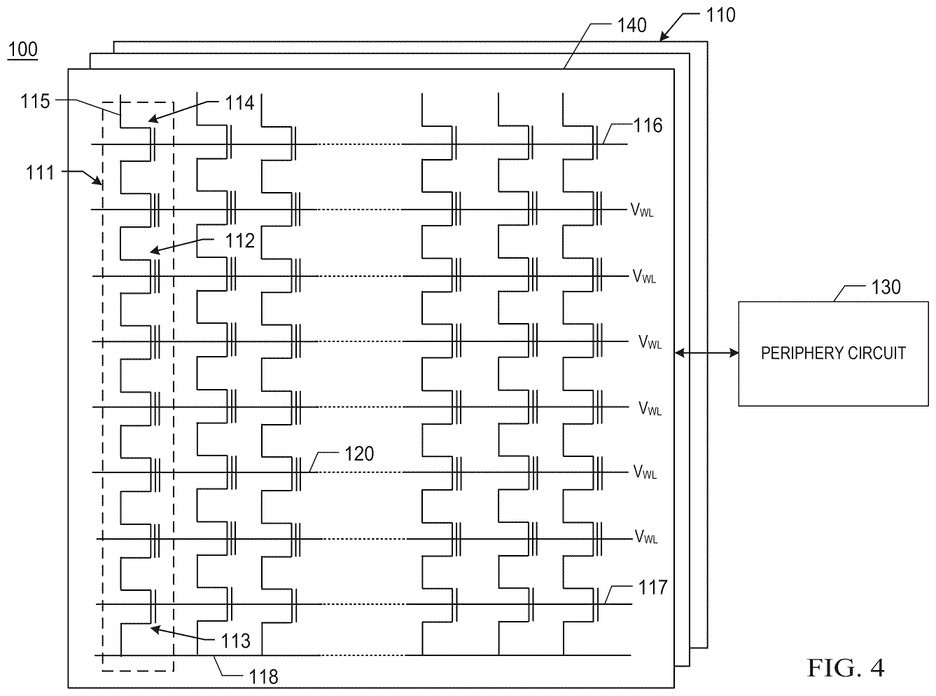

FIG. 4 is a diagram of a memory 100 provided in an example of the present disclosure. As shown in FIG. 4, the memory 100 includes: a memory array 110 including a plurality of memory cell rows; a plurality of word lines 120 coupled to the plurality of memory cell rows respectively; and a peripheral circuit 130 coupled to the plurality of word lines 120 and configured to perform a verification operation or program operation on a selected memory cell row in the plurality of memory cell rows, the selected memory cell row being the memory cell row coupled with the selected word line, wherein in order to perform the verification operation or program operation, the peripheral circuit 130 is configured to perform the operating method of the memory as provided in examples of the present disclosure.

The memory array 110 may be a NAND flash memory array. As shown in FIG. 1, the NAND flash memory array includes a plurality of memory strings 111 arranged in an array on a substrate and each memory string 111 extending vertically over the substrate (not shown). In some examples, each memory string 111 includes a plurality of memory cells 112 coupled in series and stacked vertically.

As shown in FIG. 4, each memory string 111 may further include a source select gate (SSG) 113 on its bottom end and a drain select gate (DSG) 114 on its top end. The source select gate is also referred to as the lower select transistor, bottom select gate (BSG) or source select transistor, the drain select gate is also referred to as the upper select transistor, top select gate (TSG) or drain select transistor. The source select gate 113 and the drain select gate 114 may be configured to activate the selected memory string 111 during reading and program operations.

In some examples, the drain select gate 114 of each memory string 111 is coupled to a corresponding bit line 115 and data may be read from or written into the bit line 115 via an output bus (not shown).

In some examples, each memory string 111 is configured to be selected or deselected by applying a select voltage (for example, higher than the threshold voltage of the transistor having a drain select gate 114) or a deselect voltage (for example, 0V) to the corresponding drain select gate 114 via one or more DSG lines 116. And/or, in some examples, each memory string 111 is configured to be selected or deselected by applying a select voltage (for example, higher than the threshold voltage of the transistor having a source select gate 113) or a deselect voltage (for example, 0V) to the corresponding source select gate 113 via one or more SSG lines 117.

As shown in FIG. 4, the memory strings 111 may be organized into a plurality of blocks 140. For any one block 140 among the plurality of blocks 140, the block 140 may have a source line (SL) 118, and sources of all memory strings 111 in the block 140 are coupled through the source line 118 which may also be referred to as the common source line or the array common source (ACS).

It is to be noted that the source line 118 is configured to be grounded so as to ground sources of respective memory cells of memory strings in the block 140 in some subsequent operations.

Each block 140 is the basic data unit for erase operation. That is, all memory cells 112 on the same block 140 are erased at the same time. In order to erase the memory cells 112 in a selected block, it is possible to bias the source line coupled to the selected block with an erase voltage (Vers) (for example, a high positive voltage such as 20V or higher).

It will be appreciated that in some other examples, it is possible to perform the erase operation on the semi-block level, the quarter-block level or a level of any suitable number of blocks or any suitable fraction of a block.

As shown in FIG. 4, memory cells 112 in the same layer of adjacent memory strings 111 in the same block 140 may be coupled via the word line 120 that is configured to select which layer of the memory cells 112 in the block 140 is subject to the read and program operations.

Referring back to FIG. 4, the peripheral circuit 130 may be coupled to the memory array 110 through the bit line 115, the word line 120, the source line 118, the SSG line 117 and the DSG line 116. The peripheral circuit 130 may include any suitable analog, digital and hybrid signal circuits for facilitating operation of the memory array 110 by applying voltage signal and/or current signal to the memory cell 112 and sensing voltage signal and/or current signal from the memory cell 112 via the bit lines 115, word lines 120, source lines 118, SSG lines 117 and DSG lines 116.

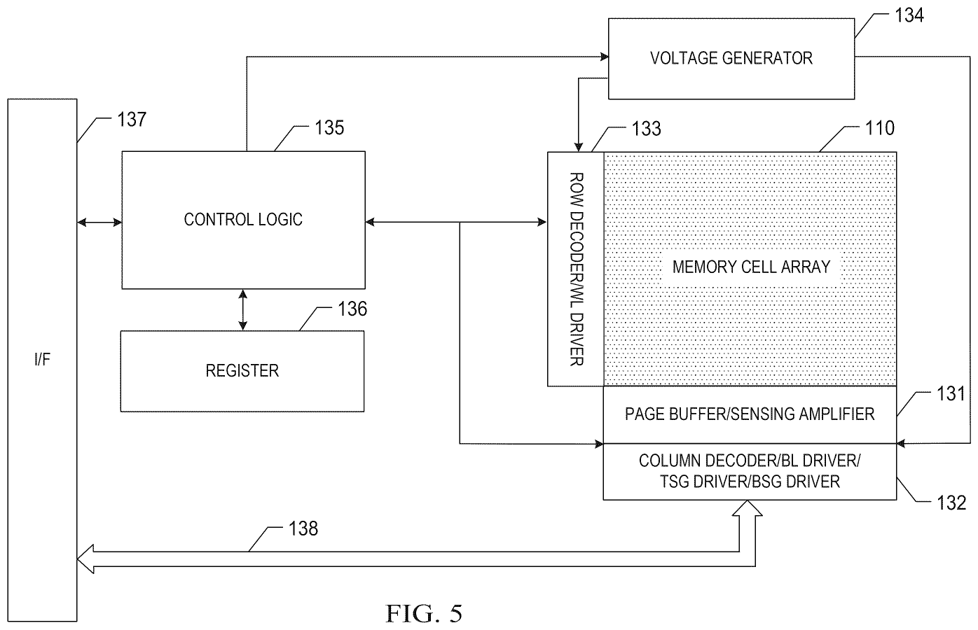

The peripheral circuit 130 may include various types of peripheral circuits formed by metal-oxide-semiconductor (MOS) technology. As an example, FIG. 5 shows some example peripheral circuits 130. The peripheral circuit 130 includes a page buffer/sense amplifier 131, a column decoder/bit line (BL) driver 132, a row decoder/word line (WL) driver 133, a voltage generator 134, a control logic 135, a register 136, an interface 137 and a data bus 138. It should be understood that in some examples, additional peripheral circuit not shown in FIG. 5 may be further included.

The page buffer/sense amplifier 131 may be configured to read and program (write) data from/to the memory array 110 according to control signal from control logic 135. As an example, the page buffer/sense amplifier 131 may store a page of programming data (writing data) to be programed into a page of the memory array 110. The page buffer/sense amplifier 131 may further perform the verification operation to ensure that the data has been properly programed into the memory cell 112 coupled to the selected word line 120. The page buffer/sense amplifier 131 may also sense a low power signal from the bit line 115 indicating the data bit stored in the memory cell 112 and amplify the small voltage swing to an identifiable logic level in the read operation.

The column decoder/bit line driver 132 may be configured to be controlled by the control logic 135 and select one or more memory strings 111 by applying a bit line voltage generated by the voltage generator 134.

The row decoder/word line driver 133 may be configured to be controlled by the control logic 135, and select/deselected the block 140 of the memory array 110 and select/deselect the word line 120 of the block 140. The row decoder/word line driver 133 may be further configured to the drive word line 120 using a word line voltage (VWL) generated by the voltage generator 134. In some examples, the row decoder/word line driver 133 may also select/deselect and drive the SSG line 117 and DSG line 116. As detailed in the following, the row decoder/word line driver 133 is configured to perform the erase operation on the memory cells 112 coupled to the (one or more) selected word lines 120.

The voltage generator 134 may be configured to be controlled by the control logic 135 and generate the word line voltage (such as read voltage, program voltage, pass voltage, local voltage and verification voltage, etc.), the bit line voltage and the source line voltage to be provided to the memory array 110.

The control logic 135 may be coupled to various circuits of the peripheral circuit described above and configured to control operations of various circuits.

The register 136 may be coupled to the control logic 135 and may include a status register, a command register and an address register to store status information, command operation codes (OP codes) and command address for controlling operation of each circuit of the peripheral circuit.

The interface (I/F) 137 may be coupled to the control logic 135, and serve as a control buffer to buffer control commands received from the host (not shown) and relay them to the control logic 135, and buffer status information received from the control logic 135 and relay them to the host. The interface 137 may be further coupled to the column decoder/bit line driver 132 via the data bus 138 and serve as a data I/O interface and a data buffer to buffer data and relay it to the memory array 110 or relay or buffer data from the memory array 110.

The above description of examples of relevant hardware of the memory has similar beneficial effects to the following examples of the method. Technique details that have not be disclosed in examples of relevant hardware of memory should be understood with reference to the description of the method examples of the present disclosure.

It is to be noted that the memory illustrated in FIGS. 4-5 is an illustration of the memory involved in examples of the present disclosure, which is not limited to the memory structure shown in FIGS. 4-5.

In some scenarios, it is possible to test current on memory pins by establishing a test table and in turn evaluate the power consumption of the memory according to the tested current. The test table includes an oscilloscope. For this test approach, on the one hand, the test process is complicated since a test table needs to be established and the test environments are limited. On the other hand, the operating principle of an oscilloscope is as follows. After each acquisition and display of data from the most recent period of time such as 2 s, resetting is required, which takes about several seconds. After resetting, data acquired in the 2 s needs to be stored, which will take more than ten seconds. Only after completing the storage, data would be acquired and the data acquired in the next 2 s would be displayed. This would cause the oscilloscope fail to acquire data in the period of time between the two periods of 2 seconds. Therefore, the oscilloscope can only test current on memory pins in several discontinuous periods, which in turn influences the accuracy of power consumption evaluation.

Based on this, an example of the present disclosure provides a memory system. In the example of the present disclosure, a current test circuit is packaged inside the memory system including memory, which allows directly testing current on memory pins by the current test circuit. So, on the one hand, it is possible to test current of the memory at any time and at any place without establishing any test table, and the test process is simple and not environment-limited. On the other hand, since the current test circuit can test current on memory pins at any time, it is possible to monitor the current data of the memory in real time in the operation of memory, thereby improving accuracy of the power consumption evaluation.

The memory system provided in examples of the present disclosure will be described in detail below.

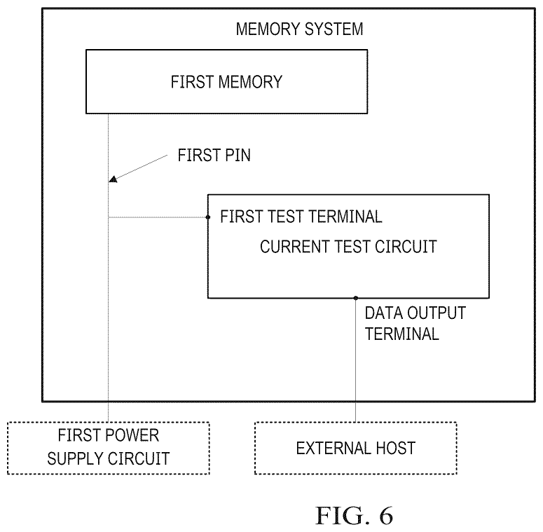

FIG. 6 is an architecture diagram of a memory system including a current test circuit as provided in an example of the present disclosure. As shown in FIG. 6, the memory system includes a first memory and a current test circuit, the first memory includes a first pin and the current test circuit includes a first test terminal and a data output terminal, wherein the first test terminal is connected with the first pin.

The first pin is configured to power the first memory with a first power supply circuit; and the current test circuit is configured to acquire the current on the first pin during the operation of the first memory and output the current on the first pin via the data output terminal.

Since the first pin is configured to power the first memory through the first power supply circuit, the first pin is also referred to as the first power pin. The first power supply circuit may be integrated inside the memory system. In some examples, the first power supply circuit may also be a power supply circuit deployed outside the memory system.

As shown in FIG. 6, the current tested by the current test circuit may be output to an external host via the data output terminal directly. Thus, during the operation of the memory system, the external host may read current data tested by the current test circuit at any time via the data output terminal, thereby monitoring the current data of the memory in real time during the operation of the memory, and in turn improving accuracy of the power consumption evaluation for the memory.

In addition, that the memory system includes a first memory and a current test circuit may be understood as that the first memory and the current test circuit are packaged on the same board to package the current test circuit inside the memory system including the memory.

Illustratively, the first memory includes a nonvolatile memory such as NAND flash memory. In such a scenario, the memory system shown in FIG. 6 may be an eMMC (embedded multi-media card) or a UFS (universal flash storage). That is, in examples of the present disclosure, it is possible to package the current test circuit inside the eMMC or UFS to test current of NAND at any time and at any place.

As another example, the first memory includes a volatile memory such as DRAM (dynamic random-access memory). In such a scenario, the memory system shown in FIG. 6 may be a DDR SDRAM (double data rate synchronous dynamic random-access memory). That is, in examples of the present disclosure, it is possible to package the current test circuit inside the DDR SDRAM to test current of DRAM at any time and at any place.

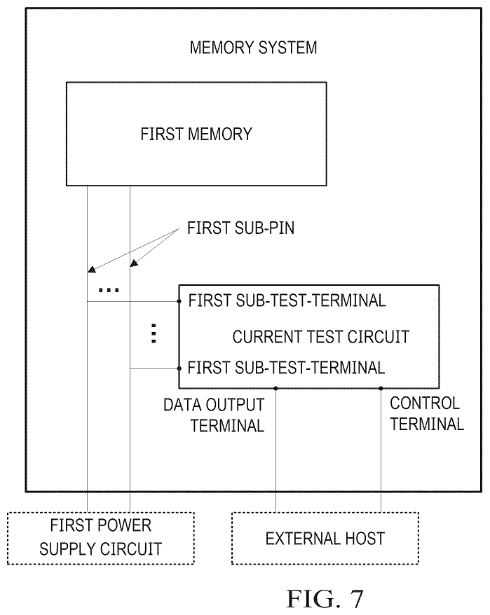

In some examples, as shown in FIG. 7, the first pin includes a plurality of first sub-pins, the first test terminal includes a plurality of first sub-test-terminals. Each first sub-test-terminal is connected with one first sub-pin. The current test circuit further includes a control terminal.

The current test circuit is further configured to receive a control instruction via the control terminal indicating that current on the target first sub-pin in the plurality of first sub-pins needs to be acquired. The current test circuit is further configured to acquire the current on the target first sub-pin in response to the control instruction.

Since the first memory generally has a plurality of pins, in some scenarios, it may be desired to test current on some specific pins. In examples of the present disclosure, as shown in FIG. 7, the external host may control the current test circuit to test the current on a certain pin (namely the target first sub-pin) via the control terminal.

The target first sub-pin may be one of the plurality of first sub-pins, or multiple of the plurality of first sub-pins.

Illustratively, in the scenario in which the first memory is a NAND, the plurality of first sub-pins may include a VCC pin, a VCCQ pin and a VCCQ2 pin. The VCC pin is configured to power the storage medium in the first memory, the VCCQ pin is configured to power the I/O circuit in the first memory and the controller controlling the first memory, and the VCCQ2 pin is configured to power the front-end interfaces in the first memory and some other low voltage modules.

When the target first sub-pin includes the VCC pin of the NAND, it is possible to test current on the VCC pin of NAND with the current test circuit provided in the examples of the present disclosure. When the target first sub-pin includes the VCCQ pin of the NAND, it is possible to test current on the VCCQ pin of NAND with the current test circuit provided in the examples of the present disclosure. When the target first sub-pin includes the VCCQ2 pin of the NAND, it is possible to test current on the VCCQ2 pin of NAND with the current test circuit provided in the examples of the present disclosure.

As another example, in the scenario in which the first memory is a DRAM, the plurality of first sub-pins may include a VDD1 pin, a VDD2H pin, a VDD2L pin and a VDDQ pin. The VDD1 pin is configured to power the core circuit such as logic circuit in the first memory, the VDD2H pin and the VDD2L pin are configured to power the auxiliary circuits such as internal address, clock and control signal generating circuits in the first memory, and the VDDQ pin is configured to power the I/O circuit in the first memory.

When the target first sub-pin includes the VDD1 pin of the DRAM, it is possible to test current on the VDD1 pin of DRAM with the current test circuit provided in the examples of the present disclosure. When the target first sub-pin includes the VDD2H pin of the DRAM, it is possible to test current on the VDD2H pin of DRAM with the current test circuit provided in the examples of the present disclosure. When the target first sub-pin includes the VDD2L pin of the DRAM, it is possible to test current on the VDD2L pin of DRAM with the current test circuit provided in the examples of the present disclosure. When the target first sub-pin includes the VDDQ pin of the DRAM, it is possible to test current on the VDDQ pin of DRAM with the current test circuit provided in the examples of the present disclosure.

In addition, illustratively, the control instruction carries a bit sequence including a plurality of bits in one-to-one correspondence with the plurality of first sub-pins. The value of the target bit in the bit sequence is the first bit value, and the value of other bits than the target bit in the bit sequence is the second bit value. The target bit is the bit corresponding to the target first sub-pin.

In such way, the external host can control the current test circuit to test current on specific pins of the first memory by sending a simple bit sequence to the current test circuit via the control terminal, which is a simple-implementation scheme and does not need complex hardware cost.

The target bit may be one bit in the bit sequence, and may also be a plurality of bits in the bit sequence. Thus, the current test circuit can not only test current on some certain pins, but also test current on all pins.

The first bit value is 1 for example, and the second bit value is 0 for example. For example, in the scenario in which the first memory is a NAND, the plurality of first sub-pins may include a VCC pin, a VCCQ pin and a VCCQ2 pin. Then the bit sequence may include three bits in one-to-one correspondence with the VCC pin, VCCQ pin and VCCQ2 pin respectively. If the bit sequence is 001, it indicates the current test circuit needs to test current on VCCQ2 pin. If the bit sequence is 011, it indicates the current test circuit needs to test current on both VCCQ pin and VCCQ2 pin. If the bit sequence is 111, it indicates the current test circuit needs to test current on VCC pin, VCCQ pin and VCCQ2 pin.

In some examples, the first bit value may be 0, and the second bit value may be 1, which will not be described in detail here.

The internal structure of the current test circuit inside the memory system provided in examples of the present disclosure will be described in detail below.

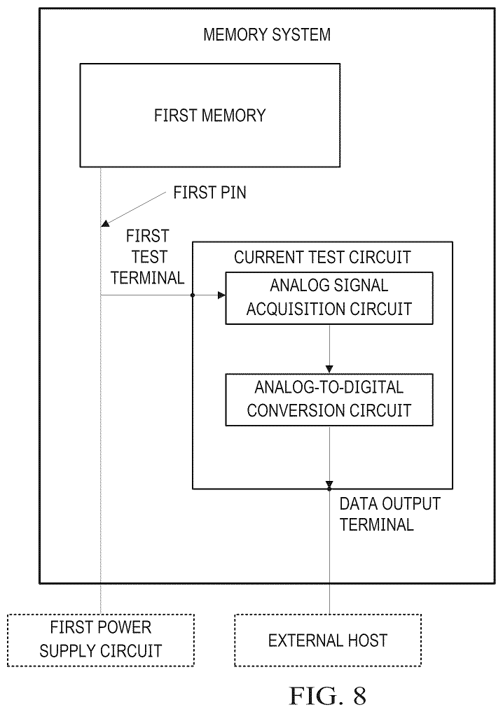

In some examples, as shown in FIG. 8, the current test circuit includes an analog signal acquisition circuit and an analog-to-digital conversion circuit. The input terminal of the analog signal acquisition circuit is connected with the first test terminal and the output terminal of the analog signal acquisition circuit is connected with the input terminal of the analog-to-digital conversion circuit. The output terminal of the analog-to-digital conversion circuit is connected with the data output terminal.

The analog signal acquisition circuit is configured to acquire current on the first pin to obtain a current analog signal; and the analog-to-digital conversion circuit is configured to convert the current analog signal into a current digital signal.

The acquired current analog signal may be directly converted into current digital signal through the analog signal acquisition circuit and the analog-to-digital conversion circuit to facilitate subsequently outputting the current digital signal to the external host via the data output terminal.

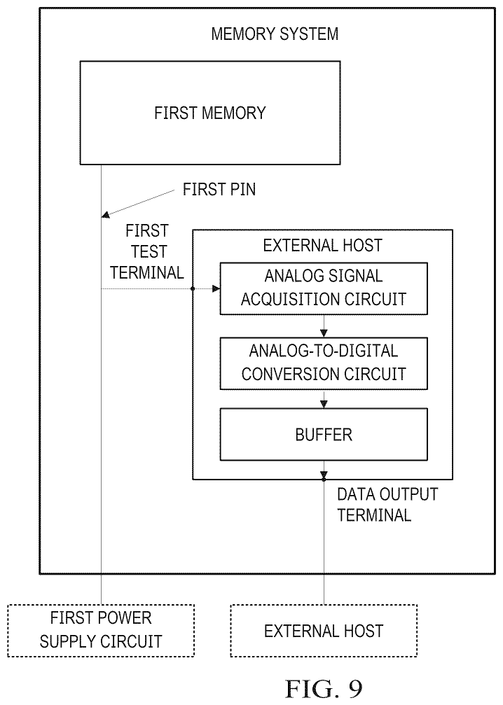

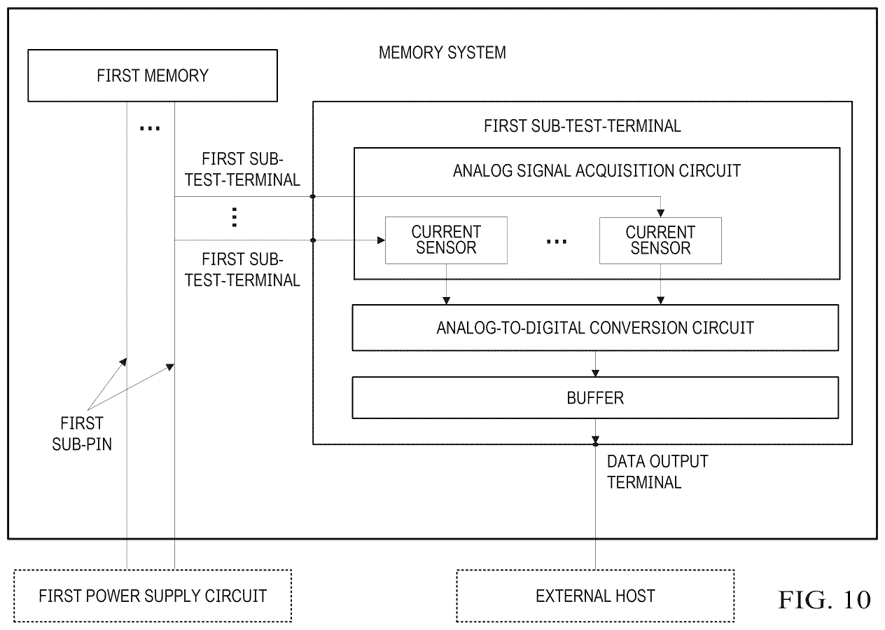

Further, in some examples, as shown in FIG. 9, the current test circuit further includes a buffer. The output terminal of the analog-to-digital conversion circuit is connected with the input terminal of the buffer and the output terminal of the buffer is connected with the data output terminal. The buffer is configured to buffer current digital signal, and further configured to output the current digital signal to the data output terminal in response to the data reading instruction received at the output terminal of the buffer.

With the buffer, the analog-to-digital conversion circuit may store the converted current digital signal in the buffer first. Then, the external host may subsequently read the current digital signal, namely the current data from the buffer according to demands, thereby improving flexibility of current test.

In some examples, in a scenario in which there is no buffer, the analog-to-digital conversion circuit may output the converted current digital signal in real time to the external host via the data output terminal and the external host stores the received current digital signal. Such a scenario requires that the external host always keeps in communication connection with the data output terminal of the current test circuit during the operation of the current test circuit.

Illustratively, the output terminal of the buffer communicates with the data output terminal through I2C (inter-integrated circuit). Since it might need to test current on a plurality of sub-pins in some scenarios, in such scenarios, the buffer may transmit current digital signal of current on the plurality of sub-pins in parallel to the external host via I2C communication.

That the buffer transmits current digital signal of current on the plurality of sub-pins in parallel to the external host means transmitting different current digital signal to the external host in different time division segments, thereby transmitting the plurality of current digital signal in parallel to the external host.

With I2C communication, only one pin needs to be provided on the buffer to be connected with the data output terminal. Therefore, it is possible to reduce the number of pins between the buffer and the data output terminal through I2C communication, thereby reducing hardware cost of the current test circuit.

Illustratively, in the scenario shown in FIG. 8 or 9, as shown in FIG. 10, the first pin includes a plurality of first sub-pins, the first test terminal includes a plurality of first sub-test-terminals, and the plurality of first sub-test-terminals are connected with the plurality of first sub-pins in one-to-one correspondence. The analog signal acquisition circuit includes a plurality of current sensors in one-to-one correspondence with the plurality of first sub-pins. The input terminal of each current sensor in the plurality of current sensors is connected with a corresponding first sub-pin via a first sub-test-terminal and the output terminal of each current sensor is connected with the input terminal of the analog-to-digital conversion circuit. Each current sensor is configured to acquire current on the corresponding first sub-pin.

It is possible to acquire current on different sub-pins respectively by providing different current sensors on different sub-pins. This implementation is simple and may reduce the hardware cost of the current test circuit.

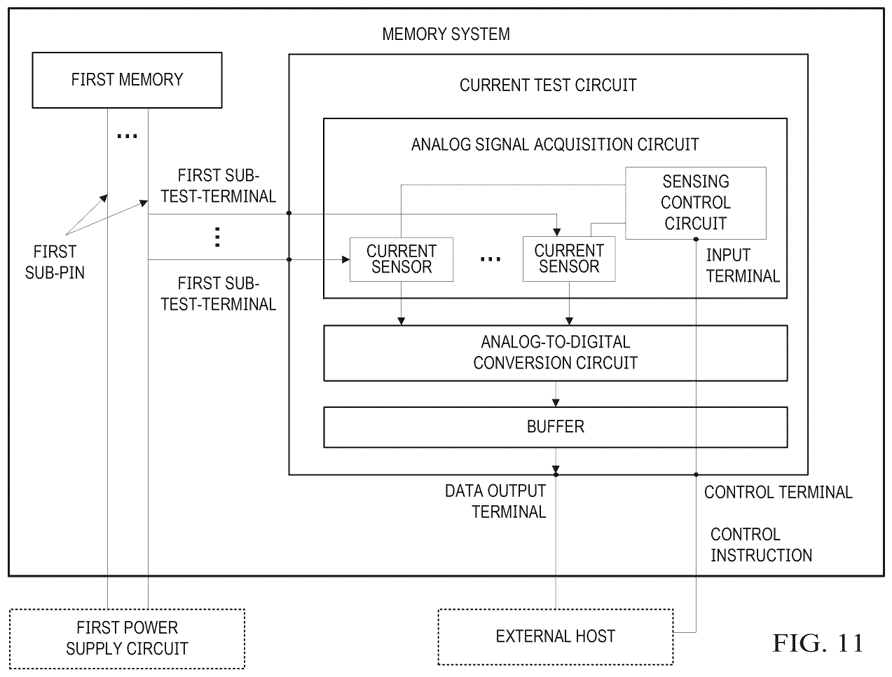

Further, as shown in FIG. 11, the analog signal acquisition circuit further includes a sensing control circuit having a plurality of control terminals connected with the control terminals of the plurality of current sensors respectively and an input terminal connected with the control terminal of the current test circuit.

The sensing control circuit is configured to control on or off of each current sensor in the plurality of current sensors in response to the control instruction received at the input terminal of the sensing control circuit.

With the sensing control circuit, it is possible to selectively acquire current on some certain sub-pins through the external host, which improves disclosure flexibility of the current acquisition circuit.

As shown in FIG. 11, the external host may input a control instruction to the sensing control circuit via the control terminal to control a specific current sensor to be turned on, thereby acquiring current on a certain sub-pin.

Illustratively, the control instruction carries a bit sequence including a plurality of bits in one-to-one correspondence with the plurality of first sub-pins. The value of the target bit in the bit sequence is the first bit value, and the value of other bits than the target bit in the bit sequence is the second bit value. The target bit is the bit corresponding to the target first sub-pin.

For the target bit, the above-described examples may be referred to for the explanation of the first bit value and the second bit value, which will not be described any more here.

For any bit, if the bit value of the bit is the first bit value, it indicates that the current sensor connected with the first sub-pin corresponding to the bit is turned on to acquire the current on the corresponding first sub-pin. If the bit value of the bit is the second bit value, it indicates that the current sensor connected with the corresponding first sub-pin is turned off, such that the current on the corresponding first sub-pin is not acquired.

The first bit value is 1 for example, and the second bit value is 0 for example. For example, in the scenario in which the first memory is a NAND, the plurality of first sub-pins may include a VCC pin, a VCCQ pin and a VCCQ2 pin. Then the bit sequence may include three bits in one-to-one correspondence with the VCC pin, VCCQ pin and VCCQ2 pin respectively. If the bit sequence is 001, it indicates the current sensor in the current test circuit that is connected with the VCCQ2 pin needs to be turned on to test current on the VCCQ2 pin. If the bit sequence is 011, it indicates the two current sensors in the current test circuit that are connected with the VCCQ pin and VCCQ2 pin need to be turned on to test current on the VCCQ pin and VCCQ2 pin. If the bit sequence is 111, it indicates the three current sensors in the current test circuit that are connected with the VCC pin, VCCQ pin and VCCQ2 pin need to be turned on to test current on the VCC pin, VCCQ pin and VCCQ2 pin.

In addition, illustratively, the sensing control circuit may be implemented with a 3-8 decoder. In some examples, the sensing control circuit may also be implemented with other decoders, which will not be illustrated in detail here.

The analog-to-digital conversion circuit may be implemented with an ADC (analog-to-digital converter) for example. The specific structure of the ADC is not limited in examples of the present disclosure. In addition, in the scenario in which the analog signal acquisition circuit includes a plurality of current sensors, the analog-to-digital conversion circuit may include a plurality of ADCs connected with the plurality of current sensors respectively to improve the data acquisition efficiency.

For example, the buffer may be implemented with a SRAM (static random-access memory). Given that the examples of the present disclosure do not require a high storage speed for the buffer, other storage medium with lower cost may be used as the buffer such as nor flash. In some examples, in order to further save the hardware cost of the current test circuit, a portion of storage space can be allocated in the storage medium of the first memory to achieve the function of the buffer.

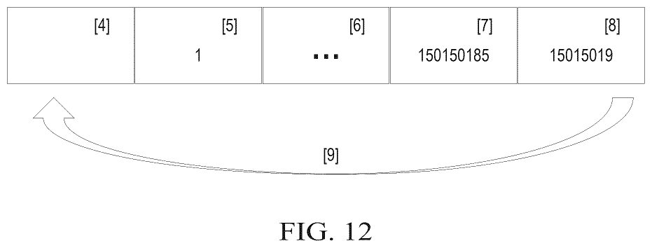

In addition, in the scenario in which the buffer is a SRAM, the manner in which the SRAM stores the current digital signal, e.g., current data may be in a scrolling manner. FIG. 12 is a diagram of a SRAM storing current data in scrolling manner as provided in an example of the present disclosure. As shown in FIG. 12, the blocks labeled as [4]/[5]/[6]/[7]/[8] are offset addresses each occupying 3 bytes. The maximum value is 0xFFFFFF. The block labeled as [6] omits the offset address with a value of 2˜15015017.

The current digital signal, e.g., the current data converted from the analog-to-digital conversion circuit are stored staring from the location of offset=0 (the block labeled as [4] in FIG. 12), and sequentially stored afterwards in turn. When the data is stored to the location of offset=15015019, it would go to the location of offset=0 to continue storing data with the existing data being overwritten rather than cleaned.

In the scenario in which the SRAM stores current data in a scrolling manner, the external host may set a reading period less than or equal to the time required for the SRAM to store data for a round, which may be understood as the time required for the SRAM to store data from a certain offset address until the next time it stores the data at that offset address. The external host reads the current data from the SRAM periodically according to the reading period. Thus, it is possible to guarantee that the user can acquire current data tested by the current test circuit at all times.

In some examples, the external host may also not set the above-described reading period, but reads the current data from SRAM at any time in response to the user's demand. In such a scenario, the user can acquire the current data tested by the current test circuit in the recent period of time due to the scrolling storage.

It is to be noted that the manner in which the current data is stored as shown in FIG. 12 is for illustration and is not limited in examples of the present disclosure.

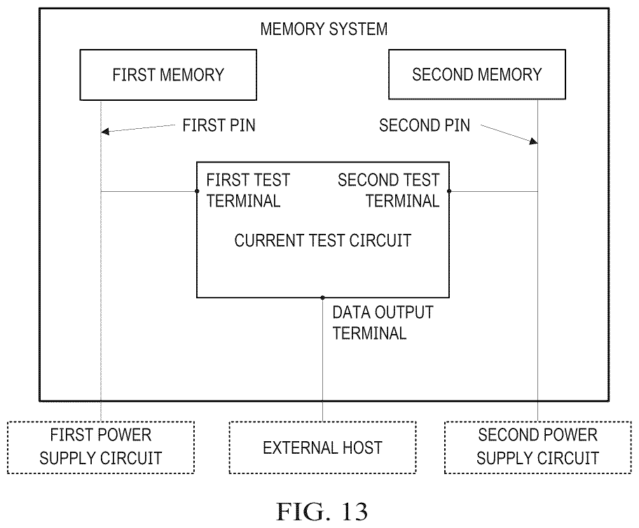

The above content is illustrated with respect to an example in which the memory system has only one memory packaged therein. In some other examples, as shown in FIG. 13, the memory system further includes a second memory having a second pin, and the current test circuit further has a second test terminal connected with the second pin.

The second pin is configured to power the second memory with a second power supply circuit; and the current test circuit is configured to acquire the current on the second pin during the operation of the second memory and output the current on the second pin via the data output terminal.

The first power supply circuit and the second power supply circuit may be integrated together or deployed at different locations, which is not limited in examples of the present disclosure.

Illustratively, the first memory includes a nonvolatile memory and the second memory includes a volatile memory.

For example, the first memory is a NAND and the second memory is a DRAM. In such a scenario, the memory system shown in FIG. 13 may be a uMCP (UFS-based multichip package). That is, in examples of the present disclosure, it is possible to package the current test circuit inside the uMCP to test current on pins of the NAND and DRAM inside uMCP at any time and at any place.

The above-described first pin, first test terminal and first power supply circuit may be referred to for the explanation of the second pin, second test terminal and second power supply circuit, which will not be described in detail herein. In addition, the specific manner in which the current test circuit tests current on the first pin of the first memory may be similarly referred to for the specific manner in which the current test circuit tests current on the second pin of the second memory, which will not be described in detail herein.

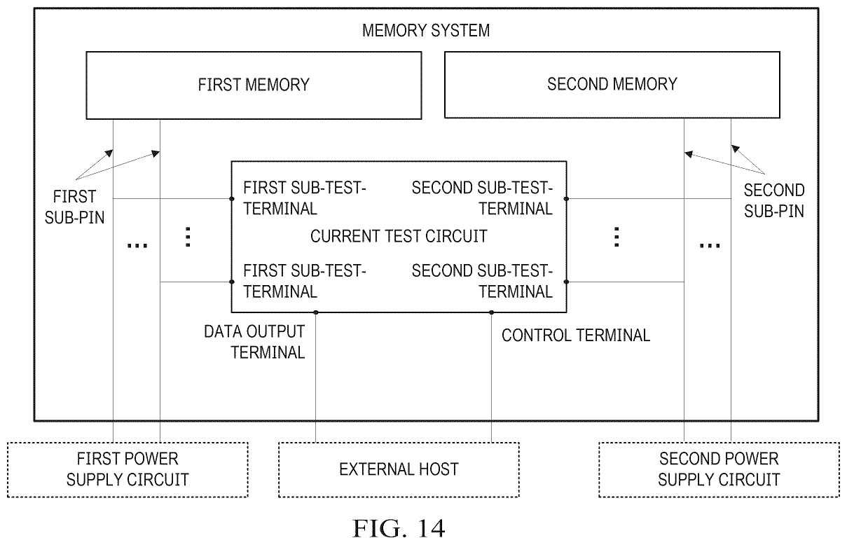

In some examples, as shown in FIG. 14, the first pin includes a plurality of first sub-pins, the first test terminal includes a plurality of first sub-test-terminals. Each first sub-test-terminal is connected with one first sub-pin. The second pin includes a plurality of second sub-pins, the second test terminal includes a plurality of second sub-test-terminals. Each second sub-test-terminal is connected with one second sub-pin. And the current test circuit further has a control terminal.

The current test circuit is further configured to receive control instructions via the control terminal indicating that current on the target sub-pin in the plurality of first sub-pins and the plurality of second sub-pins needs to be acquired. The current test circuit is further configured to acquire the current on the target sub-pin in response to the control instructions.

In the scenarios shown in FIG. 13, since the current test circuit can test current on pins of the first memory and second memory simultaneously, while in some scenarios, it may be desired to test current on some specific pins, in examples of the present disclosure, as shown in FIG. 14, the external host may control the current test circuit to test current on a certain pin (namely the target sub-pin) via the control terminal.

Illustratively, in the scenario in which the first memory is a NAND and the second memory is a DRAM, the plurality of first sub-pins may include a VCC pin, a VCCQ pin and a VCCQ2 pin, and the plurality of second sub-pins may include a VDD1 pin, a VDD2H pin, a VDD2L pin and a VDDQ pin. The external host may control the current test circuit to test current on the target sub-pin in these 7 sub-pins through control instructions.

Illustratively, the control instruction carries a bit sequence including a plurality of bits in one-to-one correspondence with the plurality of first sub-pins and the plurality of second sub-pins. The value of the target bit in the bit sequence is the first bit value, and the value of other bits than the target bit in the bit sequence is the second bit value. The target bit is the bit corresponding to the target sub-pin.

In such way, the external host can control the current test circuit to test current on specific pins of the first memory and the second memory by sending a simple bit sequence to the current test circuit via the control terminal, which is a simple-implementation scheme and does not need complex hardware cost.

The above-described examples may be similarly referred to for the explanation of the target bit, the first bit value and the second bit value, which will not be described any more here.

The first bit value is 1 for example, and the second bit value is 0 for example. For example, in the scenario in which the first memory is a NAND and the second memory is a DRAM, the plurality of first sub-pins include a VCC pin, a VCCQ pin and a VCCQ2 pin, and the plurality of second sub-pins include a VDD1 pin, a VDD2H pin, a VDD2L pin and a VDDQ pin. Then the bit sequence is one byte including eight bits, wherein the first seven bits correspond to the VCC pin, VCCQ pin, VCCQ2 pin, VDD1 pin, VDD2H pin, VDD2L pin and VDDQ pin respectively and the last bit is a reserved bit.

If the bit sequence is 00100010, it indicates the current test circuit needs to test current on the VCCQ2 pin of the NAND and the VDDQ pin of the DRAM. If the bit sequence is 01100110, it indicates the current test circuit needs to test current on the VCCQ pin and VCCQ2 pin of the NAND and the VDD2L pin and VDDQ pin of the DRAM. Other examples of the bit sequence will not be illustrated here in detail.

The current test circuit shown in FIG. 14 will be further illustrated below with the current test circuit shown in FIG. 9 as an example.

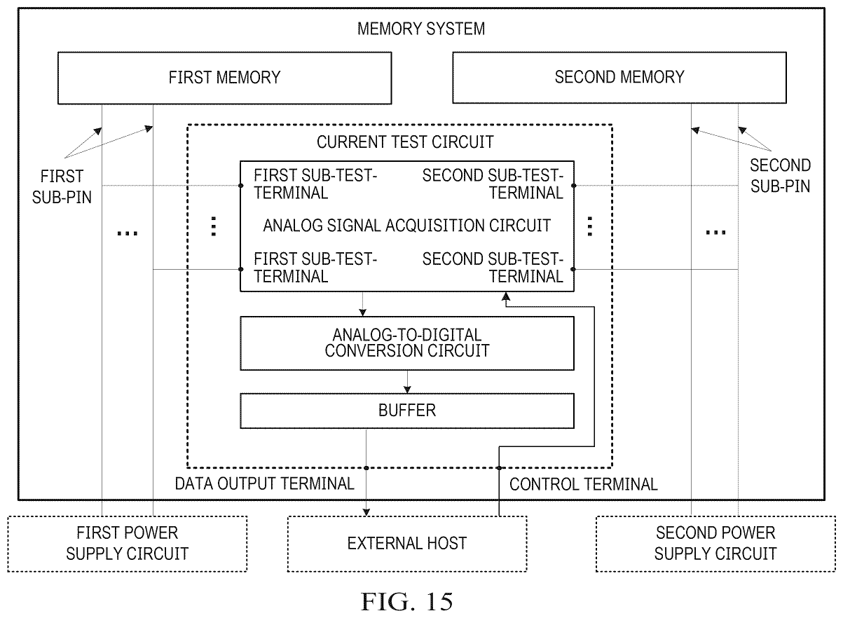

As shown in FIG. 15, the current test circuit includes an analog signal acquisition circuit, an analog-to-digital conversion circuit and a buffer. The input terminal of the analog signal acquisition circuit is connected with a plurality of first sub-test-terminals and a plurality of second sub-test-terminals respectively, and the output terminal of the analog signal acquisition circuit is connected with the input terminal of the analog-to-digital conversion circuit. The output terminal of the analog-to-digital conversion circuit is connected with the input terminal of the buffer and the output terminal of the buffer is connected with the data output terminal.

The analog signal acquisition circuit is configured to acquire current on the first sub-pin and the second sub-pin to obtain a current analog signal; and the analog-to-digital conversion circuit is configured to convert the current analog signal into a current digital signal. The buffer is configured to buffer current digital signal and further configured to output the current digital signal to the data output terminal in response to the data reading instruction received at the output terminal of the buffer.

Examples shown in the above-described FIG. 11 may be referred to for internal connections and related functions of the analog signal acquisition circuit, the analog-to-digital conversion circuit and the buffer, which will not be described in detail herein.

In addition, in the memory system shown in FIGS. 13 to 15, the components newly added in the current test circuit may be powered by a separate power supply circuit, e.g., the third power supply circuit, or in some examples by current on the first pin or the second pin, which is not limited in examples of the present disclosure.

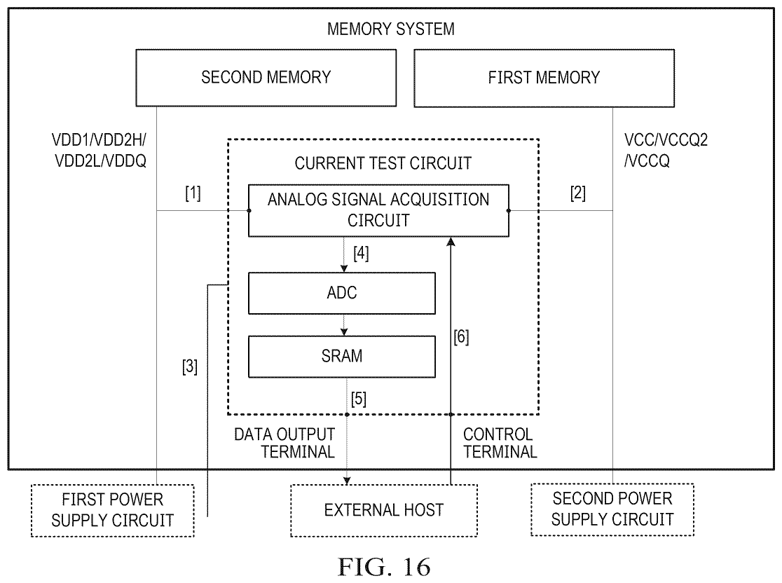

The current test circuit shown in FIG. 13 will be further illustrated below with respect to an example in which the current test circuit is deployed in uMCP. As shown in FIG. 16, the memory system is a uMCP for example, the first memory is a UFS including NAND for example, and the second memory is a DRAM for example. The above-described examples may be referred to for connection relationships among components in FIG. 16, which will not be described any more herein. In addition, 6 labels [1]-[6] are used in FIG. 16. The 6 labels in FIG. 16 will be described below.
[1] denotes that the analog signal acquisition circuit detects the power pins from the second memory such as DRAM, including VDD1/VDD2H/VDD2L/VDDQ pins. The analog signal acquisition circuit supports separately testing 1 power pin and also supports testing all power pins at the same time. It is to be noted that [1] does not indicates 1 line but includes 4 power lines. The analog signal acquisition circuit may choose to separately test current on one or more power lines and which power line is to be tested for current is controlled by [6].
[2] indicates that the analog signal acquisition circuit detects power pins of the first memory such as UFS including NAND, including VCC/VCCQ/VCCQ2 pins. The analog signal acquisition circuit supports separately testing 1 power pin and also supports testing all power pins at the same time. It is to be noted that [2] does not indicates 1 line but includes 3 power lines. The analog signal acquisition circuit may choose to separately test current on one or more power lines and which power line is to be tested for current is controlled by [6].
[3] indicates that the analog signal acquisition circuit and components such as SRAM in the current test circuit are power supplied. In FIG. 16, the connection line labeled by [3] is connected to a tin ball of the memory system such as uMCP, which is configured to access to an external power supply circuit. In some examples, it is also possible to introduce 1 power pin from the second memory such as DRAM and the first memory such as UFS respectively inside the memory system such as uMCP as the power supply circuit for the analog signal acquisition circuit and SRAM. In such a scenario, if the voltage on the power pin does not reach the specified value of operating voltage for the component in the current test circuit, it is possible to add an LDO (low dropout regulator) between the power pin and the component of the current test circuit to covert the voltage of the power pin into the required specified value of operating voltage for the component.

Illustratively, the specified value of operating voltage for SRAM is 1.2V.
[4] indicates the analog signal acquisition circuit converts the detected current analog signal into a current digital signal and stores the current digital signal e.g., the current data into the SRAM. Table 1 is a parameter table of a current digital signal provided in examples of the present disclosure.

TABLE 1

| | | Support adjustment |
|---|---|---|
| Parameter Name | Parameter Value | or not |
| Precision range | 1 micro Ampere (μA) | No |
| Current range | 1 μA-5 A | No |
| Sampling interval | 666 nanoseconds (ns)-5 | Yes |
| | milliseconds (ms) | |

As shown in Table 1, when ADC converts the current analog signal into the current digital signal, the precision range of the converted current data should be controlled to 1 μA, the range of the converted current data should be controlled to 1 μA-5 A, and the sampling interval used in the conversion may be between 666 ns to 5 ms. Specific sampling interval may be configured by the user, that is, adjusting sampling interval of ADC is supported.

Illustratively, ADC provides an interface for the user to configure the sampling interval, and the user can configure the specific value of the sampling interval through the interface, which will not be described in detail herein.
[5] indicates that the current data of SRAM is output to a tin ball, e.g., the data output terminal, of the memory system such as uMCP and in turn transmitted to the external host. The transmission manner of the current data is I2C communication, which is to reduce the number of pins between the SRAM and the data output terminal.
[6] indicates that the external host input a control instruction through the control terminal. The control instruction is one byte in which each bit corresponds to one power pin. The value on each bit indicates whether enables current test for a corresponding power pin. The bit with a value of 1 indicates enabling the current test for the corresponding power pin, namely testing the current on the corresponding power pin. The bit with a value of 0 indicates not enabling the current test for the corresponding power pin, namely not testing the current on the corresponding power pin.

Table 2 is a format table of a control instruction provided in examples of the present disclosure.

TABLE 2

| | | Corresponding |
|---|---|---|
| Description | Power pin under test | bit |
| Control | VDD1/VDD2H/VDD2L/VDDQ | 6/5/4/3/2/1/0 |
| instruction | VCC/VCCQ/VCCQ2 | |

As shown in Table 2, the control instruction is one byte in which the 0th bit corresponds to the VCCQ2 pin of the first memory such as UFS, the 1st bit corresponds to the VCCQ pin of the first memory such as UFS, the 2nd bit corresponds to the VCC pin of the first memory such as UFS, the 3rd bit corresponds to the VDDQ pin of the second memory such as DRAM, the 4th bit corresponds to the VDD2L pin of the second memory such as DRAM, the 5th bit corresponds to the VDD2H pin of the second memory such as DRAM, and the 6th bit corresponds to the VDD1 pin of the second memory such as DRAM.

In summary, the memory system provided in examples of the present disclosure has the following functions.
(1) A current test circuit is added inside the package of the memory system such that current acquisition on pins of the memory may be implemented by the way while the memory system is in normal operation. It is possible to test the current of the memory at any time and at any place without establishing a test table. The test process is simple and not limited by the environment. At the same time, it is also possible to reduce the test cost.
(2) Since the current test circuit can test current on pins of the memory at any time, it is possible to monitor the current data of the memory in real time in the operation of memory, which not only can improve the efficiency of acquiring the current data, but also can improve the accuracy of the acquired current data.
(3) Since it is possible to monitor the current data of memory in real time in the operation of memory, the tested current data can reflect the memory operation state more really, thereby facilitating analyzing the behavior and power consumption of the memory system.

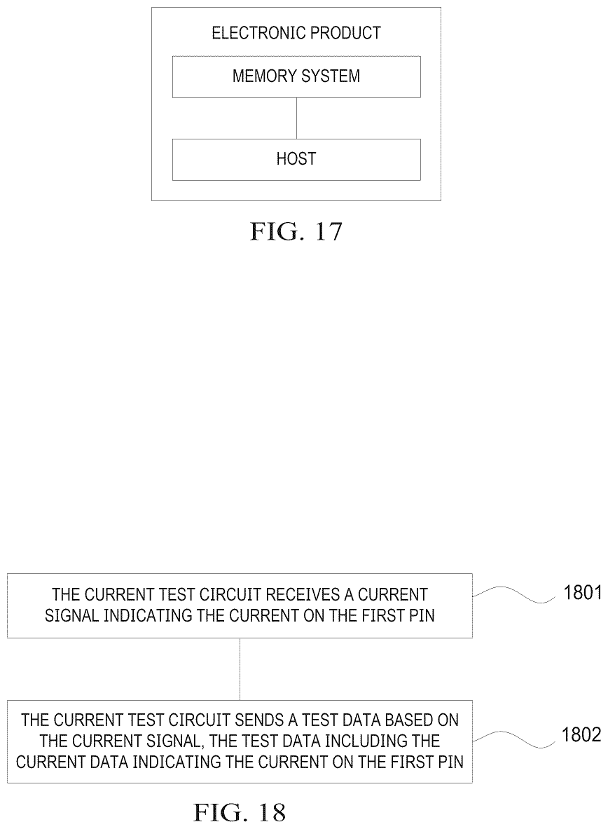

In addition, an example of the present disclosure further provides an electronic product. FIG. 17 is a structure diagram of an electronic product provided in an example of the present disclosure. As shown in FIG. 17, the electronic product includes a memory system and a host coupled to the memory system and configured to control the memory system.

The memory system in FIG. 17 may be any one of the memory systems described in FIGS. 6-16.

Furthermore, an example of the present disclosure further provides an operating method of a memory system including a first memory having a first pin, and a current test circuit. As shown in FIG. 18, the method includes the following operations.

Operation 1801: The current test circuit receives a current signal indicating the current on the first pin.

The current signal in operation 1801 may be specifically understood as the current analog signal acquired by the current test circuit on the first pin.

Operation 1802: The current test circuit sends a test data based on the current signal, which includes the current data indicating current on the first pin.

Relevant contents in the above-described FIGS. 7-11 may be referred to for how the current test circuit sends the test data based on the current signal, which will not be described any more herein.

In some examples, the first pin includes a plurality of first sub-pins. Before the current test circuit receives the current signal, the current test circuit receives a control instruction indicating that it is required to acquire current on the target first sub-pin in the plurality of first sub-pins.

In such a scenario, the implementation for the current test circuit to receive the current signal may be as follows. The current test circuit receives a target current signal indicating the current on the target first sub-pin, wherein the test data includes target current data indicating the current on the target first sub-pin.

Illustratively, the control instruction carries a bit sequence including a plurality of bits in one-to-one correspondence with the plurality of first sub-pins. The value of target bit in the bit sequence is the first bit value, and the value of other bits than the target bit in the bit sequence is the second bit value. The target bit is the bit corresponding to the target first sub-pin.

The above-described examples may be similarly referred to for relevant contents of the control instruction, which will not be described any more here.

In some examples, the current test circuit includes a buffer for storing the test data. In such a scenario, the implementation for the current test circuit to send the test data based on the current signal may be as follows. The buffer receives the data reading instruction and sends the test data in response to the data reading instruction.

The above-described examples may be similarly referred to for relevant contents of the buffer, which will not be described any more here.

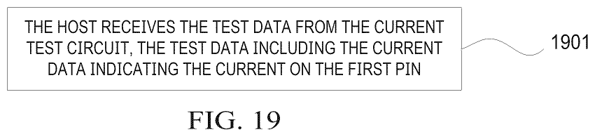

Furthermore, an example of the present disclosure further provides another operating method of a memory system including a first memory having a first pin, and a current test circuit. As shown in FIG. 19, the method includes the following operations.

Operation 1901: The host receives the test data from the current test circuit, the test data includes the current data indicating current on the first pin.

In some examples, the first pin includes a plurality of first sub-pins. In such a scenario, before the host receives the test data from the current test circuit, the host sends a control instruction to the current test circuit indicating that it is required to acquire current on the target first sub-pin in the plurality of first pins, wherein the test data includes the current data indicating current on the target first sub-pin.

Illustratively, the control instruction carries a bit sequence including a plurality of bits in one-to-one correspondence with the plurality of first sub-pins. The value of target bit in the bit sequence is the first bit value, and the value of other bits than the target bit in the bit sequence is the second bit value. The target bit is the bit corresponding to the target first sub-pin.

In some examples, before the host receives the test data from the current test circuit, the host sends a data reading instruction to the buffer in the current test circuit, wherein the buffer stores the test data.

The implementations of methods shown in FIGS. 18 and 19 have been described in detail in the above examples and will not be described any more herein.

Terms “first”, “second” etc. in examples of the present disclosure are used to distinguish similar objects and not necessarily to describe particular order or sequential order. It should be understood that “first”, “second” etc. may be interchanged in terms of specific order or sequence if allowed to allow examples of the present disclosure described herein to be implemented in an order other than those illustrated or described herein.

It should be understood that “some examples” as mentioned throughout the description means that particular features, structures, or characteristics related to the example are included in at least one example of the present disclosure. Therefore, “in some examples” or “in some other examples” occurring throughout the description does not necessarily refer to the same example. In addition, these particular features, structures, or characteristics may be incorporated in one or more examples in any suitable manners.

It is to be noted that in the specification, terms “include”, “comprise” or any other variants thereof are intended to encompass non-exclusive inclusion such that a process, method, article or device including a series of elements includes not only those elements, but also other elements that have not been listed explicitly, or further includes elements inherent in the process, method, article or device. Without any further limitations, an element defined by expression “including a . . . ” does not exclude additional identical elements in the process, method, article or device including said element.

What have been described above are only examples of the present disclosure. The scope of the present disclosure is not limited thereto. Variations and substitutions that easily occur to any one skilled in the art in the technical scope disclosed by the present disclosure should be encompassed in the scope of the present disclosure. Therefore, the scope of the present disclosure should be determined by the scope of the claims.

What is claimed is:

1. A memory system, the memory system comprising a first memory and a current test circuit, the first memory having a first pin, the current test circuit having a first test terminal and a data output terminal, with the first test terminal connected with the first pin;
the first pin is configured to power the first memory through a first power supply circuit; and
the current test circuit is configured to acquire current on the first pin during operation of the first memory and output the current on the first pin via the data output terminal.

2. The memory system of claim 1, wherein the first pin comprises a plurality of first sub-pins, the first test terminal comprises a plurality of first sub-test-terminals, each first sub-test-terminal is connected with one first sub-pin, and the current test circuit further has a control terminal;
the current test circuit is further configured to receive a control instruction via the control terminal indicating that current on a target first sub-pin in the plurality of first sub-pins needs to be acquired; and
the current test circuit is further configured to acquire the current on the target first sub-pin in response to the control instruction.

3. The memory system of claim 2, wherein:
the control instruction carries a bit sequence comprising a plurality of bits in one-to-one correspondence with the plurality of first sub-pins;
a value of target bit in the bit sequence is a first bit value;
a value of other bits than the target bit in the bit sequence is a second bit value; and
the target bit is a bit corresponding to the target first sub-pin.

4. The memory system of claim 1, wherein the current test circuit comprises an analog signal acquisition circuit and an analog-to-digital conversion circuit, an input terminal of the analog signal acquisition circuit is connected with the first test terminal and an output terminal of the analog signal acquisition circuit is connected with the input terminal of the analog-to-digital conversion circuit, an output terminal of the analog-to-digital conversion circuit is connected with the data output terminal;
the analog signal acquisition circuit is configured to acquire current on the first pin to obtain a current analog signal; and
the analog-to-digital conversion circuit is configured to convert the current analog signal into a current digital signal.

5. The memory system of claim 4, wherein the current test circuit further comprises a buffer, the output terminal of the analog-to-digital conversion circuit is connected with an input terminal of the buffer and an output terminal of the buffer is connected with the data output terminal;
the buffer is configured to buffer the current digital signal; and
the buffer is further configured to output the current digital signal to the data output terminal in response to a data reading instruction received at the output terminal of the buffer.

6. The memory system of claim 5, wherein the output terminal of the buffer is in I2C communication with the data output terminal via a serial communication bus.

7. The memory system of claim 4, wherein the first pin comprises a plurality of first sub-pins, the first test terminal comprises a plurality of first sub-test-terminals, and the plurality of first sub-test-terminals are connected with the plurality of first sub-pins in one-to-one correspondence, the analog signal acquisition circuit comprises a plurality of current sensors in one-to-one correspondence with the plurality of first sub-pins, an input terminal of each current sensor in the plurality of current sensors is connected with a corresponding first sub-pin via a first sub-test-terminal and an output terminal of each current sensor is connected with the input terminal of the analog-to-digital conversion circuit; and
each current sensor is configured to acquire current on the corresponding first sub-pin.

8. The memory system of claim 7, wherein the current test circuit further has a control terminal, the analog signal acquisition circuit further comprises a sensing control circuit having a plurality of control terminals and an input terminal, the plurality of control terminals of the sensing control circuit being connected with the control terminals of the plurality of current sensors respectively, and the input terminal of the sensing control circuit being connected with the control terminal of the current test circuit; and
the sensing control circuit is configured to control on or off of each current sensor in the plurality of current sensors in response to a control instruction received at the input terminal of the sensing control circuit.

9. The memory system of any one of claim 1, wherein the memory system further comprises a second memory having a second pin, and the current test circuit further has a second test terminal connected with the second pin;
the second pin is configured to power the second memory through a second power supply circuit; and
the current test circuit is further configured to acquire a current on the second pin during operation of the second memory and output the current on the second pin via the data output terminal.

10. The memory system of claim 9, wherein the first memory comprises a nonvolatile memory and the second memory comprises a volatile memory.

11. An operating method of a memory system, wherein the memory system comprises a first memory having a first pin, and a current test circuit;
the method comprising:
receiving, by the current test circuit, a current signal indicating a current on the first pin; and
sending, by the current test circuit, test data based on the current signal, the test data comprising current data indicating the current on the first pin.

12. The method of claim 11, wherein:
the first pin comprises a plurality of first sub-pins;
before receiving, by the current test circuit, the current signal, the method further comprises:
receiving, by the current test circuit, a control instruction indicating that a current on a target first sub-pin in the plurality of first sub-pins needs to be acquired.

13. The method of claim 12, wherein receiving, by the current test circuit, the current signal comprises:
receiving, by the current test circuit, a target current signal indicating the current on the target first sub-pin; and
wherein the test data comprises target current data indicating the current on the target first sub-pin.

14. The method of claim 13, wherein the control instruction carries a bit sequence comprising a plurality of bits in one-to-one correspondence with the plurality of first sub-pins;
a value of a target bit in the bit sequence is a first bit value;
a value of other bits than the target bit in the bit sequence is a second bit value; and
the target bit is a bit corresponding to the target first sub-pin.

15. The method of claim 12, wherein the current test circuit comprises a buffer configured to store the test data;
sending, by the current test circuit, the test data based on the current signal comprises:
receiving, by the buffer, a data reading instruction; and
sending, by the buffer, the test data in response to the data reading instruction.

16. An operating method of a memory system, wherein the memory system comprises a first memory having a first pin, and a current test circuit;
the method comprising:
receiving, by a host, test data from the current test circuit, the test data comprising current data indicating a current on the first pin.

17. The method of claim 16, wherein:
the first pin comprises a plurality of first sub-pins;
before receiving, by the host, the test data from the current test circuit, the method further comprises:
sending, by the host, a control instruction to the current test circuit indicating that a current on a target first sub-pin in the plurality of first sub-pins needs to be acquired; and
wherein the test data comprises the current data indicating the current on the target first sub-pin.

18. The method of claim 17, wherein the control instruction carries a bit sequence comprising a plurality of bits in one-to-one correspondence with the plurality of first sub-pins.

19. The method of claim 18, wherein a value of a target bit in the bit sequence is a first bit value;
a value of other bits than the target bit in the bit sequence is a second bit value; and
the target bit is a bit corresponding to the target first sub-pin.

20. The method of claim 16, wherein before receiving, by the host, the test data from the current test circuit, the method further comprises:
sending, by the host, a data reading instruction to a buffer in the current test circuit, wherein the buffer stores the test data.
